(19) United States
(12) Patent Application Publication
(10) Pub. No.: US 2018/0371136 A1
(43) Pub. Date: Dec. 27, 2018

(54) IMPRINT MATERIAL

(71) Applicant: NISSAN CHEMICAL INDUSTRIES, LTD., Tokyo (JP)

(72) Inventors: Junpei KOBAYASHI, Funabashi-shi (JP); Keisuke SHUTO, Funabashi-shi (JP); Taku KATO, Funabashi-shi (JP); Masayoshi SUZUKI, Funabashi-shi (JP)

(73) Assignee: NISSAN CHEMICAL INDUSTRIES, LTD., Tokyo (JP)

(21) Appl. No.: 16/064,674

(22) PCT Filed: Dec. 16, 2016
(86) PCT No.: PCT/JP2016/087665

§ 371 Date: Jun. 21, 2018

(30) Foreign Application Priority Data
Dec. 22, 2015 (JP) 2015-250427
Feb. 19, 2016 (JP) 2016-029832

(51) Int. Cl. C08F 220/10; C08F 220/56; C08F 2/46; C08L 71/02; G03F 7/00; B29C 59/02; B29C 59/04

(52) U.S. Cl. CPC C08F 220/10; C08F 220/56; C08F 2/46; C08L 71/02; B82Y 40/00; B29C 59/022; B29C 59/04; B29C 2059/023; G03F 7/0002

(57) ABSTRACT

A novel imprint material including: (A) a compound of formula (1); (B) a compound of formula (2); (C) a compound of formula (3); (D) a compound of formula (4); and (E) a photopolymerization initiator:

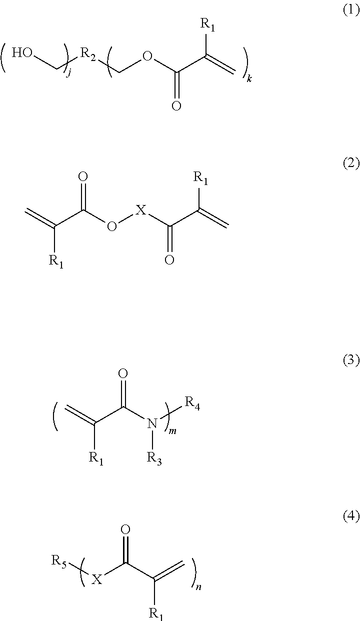

wherein each R₁ is independently a hydrogen atom or methyl group; R₂ is a divalent or trivalent hydrocarbon group; j is 0 or 1; k is 2 or 3; X is a divalent linking group having an ethylene oxide and/or a propylene oxide unit; R₃ is a hydrogen atom or alkyl group; m is 1 or 2; R₅ is a trivalent, tetravalent, pentavalent, or hexavalent organic group, which optionally has at least one hetero atom; n is an integer from 3 to 6; where m is 1, R₄ is an alkyl group optionally substituted with at least one substituent; and where m is 2, R₄ is an alkylene group optionally substituted with at least one substituent.

### TECHNICAL FIELD

The present invention relates to an imprint material (composition for forming a film for imprinting) and to a film produced from the material and having a pattern transferred thereon. More specifically, the present invention relates to a film produced from the material and having a pattern transferred thereon, which is excellent in adhesion to a substrate, scratch resistance, and wiping resistance under high load.

### BACKGROUND ART

In 1995, Professor Chou, who is currently at Princeton University, and others developed a novel technology called nanoimprint lithography (Patent Document 1). Nanoimprint lithography is a technology in which a mold having any pattern is contacted with a base material on which a resin film is formed, and the resin film is pressed while applying an external stimulation such as heat or light to form an intended pattern on the cured resin film. Nanoimprint lithography has the advantage of allowing nanoscale processing simply and inexpensively, compared to conventional photolithography and the like in the manufacture of semiconductor devices.

Thus, since nanoimprint lithography is expected to be applied to the manufacture of semiconductor devices, optical devices, displays, storage media, biochips, and the like, instead of the photolithography technique, various reports have been made regarding curable compositions for photonanoimprint lithography used for nanoimprint lithography (Patent Documents 2 and 3).

In photonanoimprint lithography, a roll-to-roll method has been developed as a method for mass-producing a pattern-transferred film with high efficiency. A mainstream roll-to-roll method conventionally proposed in photonanoimprint lithography is a method that uses a flexible film as a base material, and uses, as a material to be used for nanoimprint lithography (hereinafter abbreviated as an “imprint material”), a solventless-type material to which no solvent is added to avoid changes in pattern dimensions.

### PRIOR ART DOCUMENTS

### Patent Documents

Patent Document 1: Specification of U.S. Pat. No. 5,772,905

Patent Document 2: Japanese Patent Application Publication No. 2008-105414 (JP 2008-105414 A)

Patent Document 3: Japanese Patent Application Publication No. 2008-202022 (JP 2008-202022 A)

### SUMMARY OF THE INVENTION

### Problem to be Solved by the Invention

As described above, a solventless-type material is used as a conventionally proposed imprint material. However, such an imprint material may not establish favorable adhesion between the film after imprinting and the base material film. Moreover, in a product such as a solid-state imaging device, a solar cell, an LED device, or a display, scratch resistance may be required for a projection-and-recess shape produced as an optical member inside or on the surface of the product. Furthermore, when the projection-and-recess shape is adopted on the surface of the above-described product, contamination on the surface may be removed under high load with a tissue, a cloth, or the like. In this case, a collapse of projections in the projection-and-recess shape must be prevented. However, although various imprint materials have been disclosed, no specific studies or reports have been made regarding a material that has sufficient adhesion to a film base material, and is excellent in scratch resistance and surface wiping resistance, i.e., the above-described collapse of projections does not occur when the surface is wiped under high load.

The present invention has been made in view of the above-described circumstances, and a problem to be solved by the present invention is to provide an imprint material that forms a film having sufficient adhesion to a film base material and excellent scratch resistance, and having surface wiping resistance under high load, when the imprint material is used to form a resin film.

### Means for Solving the Problem

As a result of diligent study to solve the above-described problem, the inventors of the present invention used, as an imprint material, a material containing a predetermined compound having a polymerizable group at an end, a compound having a propylene oxide unit and/or an ethylene oxide unit and having a polymerizable group at an end, a predetermined (meth)acrylamide compound, a compound having a predetermined ethylene oxide unit and having a polymerizable group at an end, and a photopolymerization initiator, thereby making the following findings, and completing the present invention. That is, there is excellent adhesion between a film having a projection-and-recess shape transferred thereon and a base material; even when the surface of the film having the projection-and-recess shape transferred thereon is subjected to a steel wool scratch test, it generates almost no scratches; and even when the surface of the film having the projection-and-recess shape transferred thereon is wiped under high load, a collapse of projections on the projection-and-recess shape does not occur.

In summary, a first aspect of the present invention relates to:

an imprint material comprising a component (A), a component (B), a component (C), a component (D), and a component (E):

(A) a compound of formula (1);

(B) a compound of formula (2);

(C) a compound of formula (3);

(D) a compound of formula (4); and

(E) a photopolymerization initiator:

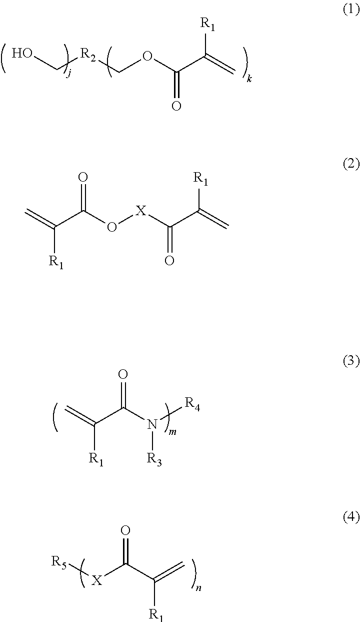

(wherein each R₁ is independently a hydrogen atom or a methyl group; R₂ is a divalent or trivalent hydrocarbon group having a carbon atom number of 1 to 5; j is 0 or 1; k is 2 or 3; X is a divalent linking group having an ethylene oxide unit and/or a propylene oxide unit; R₃ is a hydrogen atom or a C₁₋₃ alkyl group; m is 1 or 2; R₅ is a trivalent, tetravalent, pentavalent, or hexavalent organic group having a carbon atom number of 3 to 10, which optionally has at least one hetero atom; n is an integer from 3 to 6;

where m is 1, R₄ is a C₁₋₁₂ alkyl group optionally substituted with at least one substituent selected from the group consisting of a hydroxy group, a carboxy group, an acetyl group, an amino group in which one or two hydrogen atoms are optionally substituted with a methyl group or methyl groups, a sulfo group, and a C₁₋₄ alkoxy group; and

where m is 2, R₄ is a C₁₋₁₂ alkylene group optionally substituted with at least one substituent selected from the group consisting of a hydroxy group, a carboxy group, an acetyl group, an amino group in which one or two hydrogen atoms are optionally substituted with a methyl group or methyl groups, a sulfo group, and a C₁₋₄ alkoxy group.)

A second aspect of the present invention relates to the imprint material according to the first aspect, wherein the component (B) and the component (D) comprise one or two compounds of formulae (2a) and (4a), respectively:

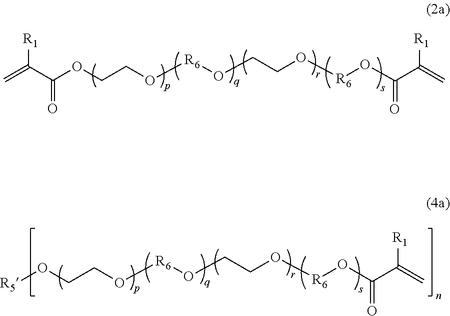

(wherein each R₁ is independently a hydrogen atom or a methyl group; R₅′ is a trivalent, tetravalent, pentavalent, or hexavalent organic group having a carbon atom number of 3 to 10 or a trivalent, tetravalent, pentavalent, or hexavalent hydrocarbon group having a carbon atom number of 3 to 10, which has an ether bond in a main chain; R₆ is a trimethylene group or a propylene group; and p, q, r, and s are each independently an integer of 0, or 1 or more, and satisfy the relational expression 1 (p+q+r+s)≤30).

A third aspect of the present invention relates to the imprint material according to the first or second aspect, wherein a content of the component (A) is 1% by mass or more and 40% by mass or less, based on a total mass of the components (A), (B), (C), and (D).

A fourth aspect of the present invention relates to the imprint material according to any one of the first to third aspects, wherein a content of the component (C) is 1% by mass or more and 40% by mass or less, based on a total mass of the components (A), (B), (C), and (D).

A fifth aspect of the present invention relates to the imprint material according to any one of the first to fourth aspects, further comprising, as a component (F), one or two compounds of formula (5):

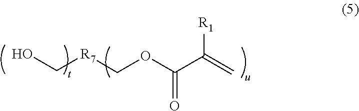

(wherein each R₁ is independently a hydrogen atom or a methyl group; R₇ is a tetravalent, pentavalent, or hexavalent organic group having a carbon atom number of 1 to 9 or a tetravalent, pentavalent, or hexavalent hydrocarbon group having a carbon atom number of 1 to 9, which has an ether bond in a main chain; t is 0 or 1; and u is an integer from 3 to 6).

A sixth aspect of the present invention relates to the imprint material according to any one of the first to fifth aspects, further comprising a silicone compound as a component (G).

A seventh aspect of the present invention relates to the imprint material according to any one of the first to sixth aspects, further comprising a surfactant as a component (H).

An eighth aspect of the present invention relates to the imprint material according to any one of the first to seventh aspects, further comprising a solvent as a component (I).

A ninth aspect of the present invention relates to a method for producing a film having a pattern transferred thereon, comprising the steps of applying the imprint material according to any one of the first to eighth aspects to a base material to form a film; and bringing a mold on which a pattern is formed into contact with the film by using a photoimprinting apparatus, pressure-bonding the film to the mold, photocuring the film, and then releasing the film from the mold to thereby transfer the pattern onto the film.

### Effects of the Invention

The imprint material of the present invention contains a predetermined compound having a polymerizable group at an end, a compound having a propylene oxide unit and/or an ethylene oxide unit and having a polymerizable group at an end, and a predetermined (meth)acrylamide compound; therefore, a cured film produced from the imprint material achieves sufficient adhesion to a film base material, and has high scratch resistance, and when the surface of the cured film having a projection-and-recess shape transferred thereon is wiped under high load, a collapse of projections does not occur.

Moreover, the imprint material of the present invention is capable of photocuring, and a portion of the pattern does not peel off during release from the mold surface; therefore, a film on which a desired pattern is precisely formed can be obtained. Thus, a satisfactory photoimprint pattern can be formed.

Moreover, the imprint material of the present invention can form a film on any base material, and the formed film has sufficient adhesion to a film base material, and has scratch resistance. Furthermore, when the surface of the film having a projection-and-recess shape transferred thereon is wiped under high load, a collapse of projections does not occur. Thus, a pattern-transferred film formed after imprinting can be suitably used in the manufacture of optical members in which scratch resistance and resistance to wiping of contamination are required, such as solid-state imaging devices, solar cells, LED devices, and displays.

Moreover, by changing the type and the content of the compound as the component (B), the curing rate, the dynamic viscosity, and the film thickness of the imprint material of the present invention can be controlled. Thus, using the imprint material of the present invention, materials can be designed to adapt to the type of device to be produced and the types of an exposure process and a baking process. This can increase the process margin, and the imprint material of the present invention can be suitably used in the manufacture of optical members.

### MODES FOR CARRYING OUT THE INVENTION

[Component (A): Compound of Formula (1)] The compound as the component (A) is a compound of formula (1):

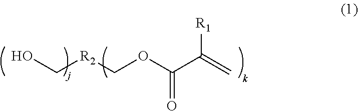

(wherein each R₁ is independently a hydrogen atom or a methyl group; R₂ is a divalent or trivalent hydrocarbon group having a carbon atom number of 1 to 5; j is 0 or 1; and k is 2 or 3).

Specific examples of the compound of formula (1) include trimethylolpropane triacrylate, pentaerythritol triacrylate, trimethylolpropane trimethacrylate, and pentaerythritol trimethacrylate.

The compound of formula (1) is commercially available, and specific examples thereof include NK ester 701A, 701, A-HD-N, A-NPG, NPG, A-TMPT, and TMPT (from Shin-Nakamura Chemical Co., Ltd.), ARONIX (registered trademark)

M309 (from Toagosei Co., Ltd.), and KAYARAD NPGDA and TMPTA (from Nippon Kayaku Co., Ltd.).

The above-described compounds as the component (A) can be used alone or in combination of two or more.

The content of the component (A) in the imprint material of the present invention is preferably 1% by mass or more and 40% by mass or less, based on a total mass of the component (A), and the below-described components (B), (C), (D), and (F). If the content of the component (A) is less than 1% by mass, when a surface of a film obtained by photoimprinting having a projection-and-recess shape transferred thereon is wiped under high load, a collapse of projections is likely to occur. On the other hand, if the component (A) is added in an amount over 40% by mass, scratch resistance will sharply decrease.

[Component (B): Compound of Formula (2)]

The compound as the component (B) is a compound of formula (2):

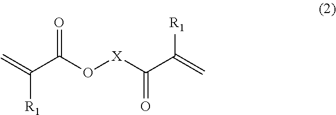

(wherein each R₁ is independently a hydrogen atom or a methyl group; and X is a divalent linking group having an ethylene oxide unit and/or a propylene oxide unit).

As used herein, “propylene oxide unit” denotes, for example, “—CH₂CH(CH₃)O—”, “—CH(CH₃)CH₂O—”, or “—CH₂CH₂CH₂O—”, and “ethylene oxide unit” denotes, for example, “—CH₂CH₂O—”.

Among the compounds of formula (2), specific examples of compounds having one or more ethylene oxide units in one molecule include ethylene glycol di(meth)acrylate, polyethylene glycol di(meth)acrylate, ethoxylated bisphenol A di(meth)acrylate, and isocyanuric acid ethylene oxide-modified diacrylate. As used herein, “(meth)acrylate compound” refers to both an acrylate compound and a methacrylate compound. For example, (meth)acrylic acid refers to both acrylic acid and methacrylic acid.

Among the compounds of formula (2), the compounds having one or more ethylene oxide units in one molecule are commercially available, and specific examples thereof include NK ester A-200, A-400, A-600, A-1000, 1G, 2G, 3G, 4G, 9G, 14G, 23G, ABE-300, A-BPE-4, A-BPE-6, A-BPE-10, A-BPE-20, A-BPE-30, BPE-80N, BPE-100N, BPE-200, BPE-500, BPE-900, and BPE-1300N (from Shin-Nakamura Chemical Co., Ltd.), KAYARAD (registered trademark) PEG400DA (from Nippon Kayaku Co., Ltd.), ARONIX (registered trademark) M-215 and M-240 (from Toagosei Co., Ltd.), and FANCRYL (registered trademark) FA-220M (from Hitachi Chemical Co., Ltd.).

Among the compounds of formula (2), specific examples of compounds having one or more propylene oxide units in one molecule include dipropylene glycol di(meth)acrylate, tripropylene glycol di(meth)acrylate, polypropylene glycol #400 di(meth)acrylate, and polypropylene glycol #700 di(meth)acrylate.

Among the compounds of formula (2), the compounds having one or more propylene oxide units in one molecule are commercially available, and specific examples thereof include NK ester APG-100, APG-200, APG-400, APG-700, 3PG, and 9PG (from Shin-Nakamura Chemical Co., Ltd.), ARONIX (registered trademark) M-220, M-225, and M-270 (from Toagosei Co., Ltd.), and FANCRYL (registered trademark) FA-P240A and FA-P270A (from Hitachi Chemical Co., Ltd.).

Among the compounds of formula (2), specific examples of compounds having one or more each of ethylene oxide units and propylene oxide units in one molecule include ethylene oxide-propylene oxide copolymer di(meth)acrylic acid ester, propoxylated ethoxylated bisphenol A di(meth)acrylate, and ethoxylated polypropylene glycol #700 di(meth)acrylate.

Among the compounds of formula (2), the compounds having one or more each of ethylene oxide units and propylene oxide units in one molecule are commercially available, and specific examples thereof include A-1000PER and A-B1206PE (from Shin-Nakamura Chemical Co., Ltd.), and FANCRYL (registered trademark) FA-023M (from Hitachi Chemical Co., Ltd.).

The above-described compounds as the component (B) can be used alone or in combination of two or more. The compound is preferably, for example, a compound of formula (2a):

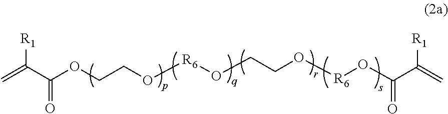

(wherein each R₁ is independently a hydrogen atom or a methyl group; R₆ is a trimethylene group or a propylene group; and p, q, r, and s are each independently an integer of 0 or more, and satisfy the relational expression 1≤(p+q+r+s)≤30). When two types of compounds of formula (2a) are used, examples of combinations include a combination of a compound having one or more ethylene oxide units in one molecule and a compound having one or more each of propylene oxide units and ethylene oxide units in one molecule; a combination of a compound having one or more ethylene oxide units in one molecule and a compound having one or more propylene oxide units in one molecule; and a combination of a compound having one or more propylene oxide units in one molecule and a compound having one or more each of propylene oxide units and ethylene oxide units in one molecule.

The content of the component (B) in the imprint material of the present invention is, for example, 5% by mass or more and 80% by mass or less, preferably 50% by mass or more and 80% by mass or less, based on a total mass of the components (A) and (B), and the below-described components (C), (D), and (F).

The component (B) in the imprint material of the present invention can impart scratch resistance to a film after pattern transfer. The component (B) can also assist in causing bleed-out of the below-described silicone compound as the component (G) during curing at the time of imprinting, to reduce the mold release force measured upon releasing the resulting resin film (cured coating film) from the mold surface. By changing the type and the content of the compound as the component (B), the dynamic viscosity of the imprint material, as well as the curing rate and the film thickness formed during imprint can be controlled.

[Component (C): Compound of Formula (3)]

The compound as the component (C) is a compound of formula (3), i.e., a compound having a (meth)acrylamide structure within the structure:

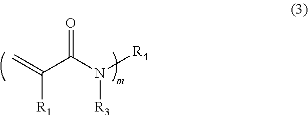

(wherein R₁ is a hydrogen atom or a methyl group; R₃ is a hydrogen atom or a C₁₋₃ alkyl group; m is 1 or 2;

where m is 1, R₄ is a C₁₋₁₂ alkyl group optionally substituted with at least one substituent selected from the group consisting of a hydroxy group, a carboxy group, an acetyl group, an amino group in which one or two hydrogen atoms are optionally substituted with a methyl group or methyl groups, a sulfo group, and a C₁₋₄ alkoxy group; and

where m is 2, R₄ is a C₁₋₁₂ alkylene group optionally substituted with at least one substituent selected from the group consisting of a hydroxy group, a carboxy group, an acetyl group, an amino group in which one or two hydrogen atoms are optionally substituted with a methyl group or methyl groups, a sulfo group, and a C₁₋₄ alkoxy group.)

The C₁₋₁₂ alkyl group may be any of linear, branched, and cyclic alkyl groups, and specific examples thereof include methyl group, ethyl group, n-propyl group, isopropyl group, cyclopropyl group, n-butyl group, isobutyl group, sec-butyl group, tert-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group, n-heptyl group, n-octyl group, n-nonyl group, n-decyl group, n-undecyl group, and n-dodecyl group. Specific examples of the C₁₋₃ alkyl group include C₁₋₃ alkyl groups of the C₁₋₁₂ alkyl groups mentioned above.

The C₁₋₁₂ alkylene group may specifically be, for example, any of linear, branched, and cyclic alkylene groups, and specific examples thereof include methylene group, ethylene group, propane-1,2-diyl group, propane-1,3-diyl group, 2,2-dimethylpropane-1,3-diyl group, 2-ethyl-2-methylpropane-1,3-diyl group, 2,2-diethylpropane-1,3-diyl group, 2-methyl-2-propylpropane-1,3-diyl group, butane-1,3-diyl group, butane-2,3-diyl group, butane-1,4-diyl group, 2-methylbutane-2,3-diyl group, 2,3-dimethylbutane-2,3-diyl group, pentane-1,3-diyl group, pentane-1,5-diyl group, pentane-2,3-diyl group, pentane-2,4-diyl group, 2-methylpentane-2,3-diyl group, 3-methylpentane-2,3-diyl group, 4-methylpentane-2,3-diyl group, 2,3-dimethylpentane-2,3-diyl group, 3-methylpentane-2,4-diyl group, 3-ethylpentane-2,4-diyl group, 3,3-dimethylpentane-2,4-diyl group, 3,3-dimethylpentane-2,4-diyl group, 2,4-dimethylpentane-2,4-diyl group, hexane-1,6-diyl group, hexane-1,2-diyl group, hexane-1,3-diyl group, hexane-2,3-diyl group, hexane-2,4-diyl group, hexane-2,5-diyl group, 2-methylhexane-2,3-diyl group, 4-methylhexane-2,3-diyl group, 3-methylhexane-2,4-diyl group, 2,3-dimethylhexane-2,4-diyl group, 2,4-dimethylhexane-2,4-diyl group, 2,5-dimethylhexane-2,4-diyl group, 2-methylhexane-2,5-diyl group, 3-methylhexane-2,5-diyl group, and 2,5-dimethylhexane-2,5-diyl group.

Specific examples of the compound of formula (3) include (meth)acrylamide, N,N′-dimethyl(meth)acrylamide, N,N′-diethyl(meth)acrylamide, N-[3-(dimethylamino)propyl](meth)acrylamide, N-isopropyl(meth)acrylamide, N-(hydroxymethyl)(meth)acrylamide, N-(2-hydroxyethyl)(meth)acrylamide, N-dodecyl(meth)acrylamide, diacetone(meth)acrylamide, N-tert-butyl(meth)acrylamide, N-(butoxymethyl)(meth)acrylamide, 2-(meth)acrylamido-2-methylpropanesulfonic acid, 6-(meth)acrylamidohexanoic acid, N,N′-(1,2-dihydroxyethylene)bis(meth)acrylamide, and N,N′-methylenebis(meth)acrylamide. As used herein, “(meth)acrylamide compound” refers to both an acrylamide compound and a methacrylamide compound.

Among the specific examples of the compound of formula (3),

N,N′-dimethyl(meth)acrylamide, N,N′-diethyl(meth)acrylamide, and N,N′-(1,2-dihydroxyethylene)bis(meth)acrylamide are preferred, and in particular, N,N′-dimethylacrylamide, N,N′-diethylacrylamide, and N,N′-(1,2-dihydroxyethylene)bisacrylamide are most preferred, from the viewpoint of achieving adhesion with an extremely small amount of the compound added.

The above-described compounds as the component (C) can be used alone or in combination of two or more.

The content of the component (C) in the imprint material of the present invention is, for example, 1% by mass or more and 40% by mass or less, preferably 5% by mass or more and 20% by mass or less, based on a total mass of the components (A),

(B), and (C), and the below-described components (D), and (F). If the content of the component (C) is less than 1% by mass, the adhesion of a film obtained by photoimprinting to the substrate will decrease. On the other hand, if the content is over 40% by mass, the scratch resistance of the resulting film will decrease.

[Component (D): Compound of Formula (4)]

The compound as the component (D) is a compound of formula (4):

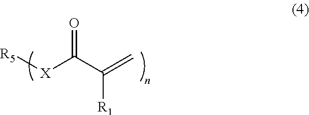

(wherein each R₁ is independently a hydrogen atom or a methyl group; X is a divalent linking group having an ethylene oxide unit and/or a propylene oxide unit; R₅ is a trivalent, tetravalent, pentavalent, or hexavalent organic group having a carbon atom number of 3 to 10, which optionally has at least one hetero atom; and n is an integer from 3 to 6).

The hetero atom is herein selected from the group consisting of, for example, an oxygen atom, a nitrogen atom, and a sulfur atom.

Among the compounds of formula (4), examples of compounds having one or more ethylene oxide units in one molecule include ethoxylated trimethylolpropane tri(meth)acrylate, ethoxylated pentaerythritol tetra(meth)acrylate, ethoxylated glycerol tri(meth)acrylate, ethoxylated dipentaerythritol hexa(meth)acrylate, and ethoxylated isocyanuric acid tri(meth)acrylate.

Among the compounds of formula (4), the compounds having one or more ethylene oxide units in one molecule are commercially available, and specific examples thereof include NK ester (registered trademark) A-TMPT-3E0, A-TMPT-9E0, ATM-35E, A-GLY-9E, A-GLY-20E, and A-9300 (from Shin-Nakamura Chemical Co., Ltd.), Viscoat #360 (from Osaka Organic Chemical Industry Ltd.), KAYARAD (registered trademark) DPEA-12 (from Nippon Kayaku Co., Ltd.), and ARONIX (registered trademark) M-315 (from Toagosei Co., Ltd.).

Among the compounds of formula (4), examples of compounds having one or more propylene oxide units in one molecule include glyceroltripropoxytri(meth)acrylate.

Among the compounds of formula (4), the compounds having one or more propylene oxide units in one molecule are commercially available, and specific examples thereof include KAYARAD (registered trademark) GPO-303 (from Nippon Kayaku Co., Ltd.).

The above-described compounds as the component (D) can be used alone or in combination of two or more. The compound is preferably, for example, a compound of formula (4a):

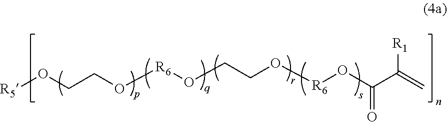

(wherein each R₁ is independently a hydrogen atom or a methyl group; R₅′ is a trivalent, tetravalent, pentavalent, or hexavalent organic group having a carbon atom number of 3 to 10 or a trivalent, tetravalent, pentavalent, or hexavalent hydrocarbon group having a carbon atom number of 3 to 10, which has an ether bond in a main chain; R₆ is a trimethylene group or a propylene group; and p, q, r, and s are each independently an integer of 0, or 1 or more, and satisfy the relational expression 1≤(p+q+r+s)≤30).

When two types of compounds of formula (4a) are used, examples of combinations include a combination of a compound having one or more ethylene oxide units in one molecule and a compound having one or more propylene oxide units in one molecule.

The content of the component (D) in the imprint material of the present invention is, for example, 5% by mass or more and 70% by mass or less, preferably 10% by mass or more and 50% by mass or less, based on a total mass of the components (A), (B), (C), and (D), and the below-described component (F). If the content of the component (D) is less than 5% by mass, the scratch resistance of a film obtained by photoimprinting will decrease. On the other hand, if the content is over 70% by mass, the adhesion of the resulting film to the substrate will decrease.

[Component (E): Photopolymerization Initiator]

The photopolymerization initiator as the component (E) is not particularly limited so long as it has absorption corresponding to the light source used for photocuring. Examples of the photopolymerization initiator include organic peroxides such as tert-butylperoxy-iso-butyrate, 2,5-dimethyl-2,5-bis(benzoyldioxy)hexane, 1,4-bis[α-(tert-butyldioxy)-iso-propoxy]benzene, di-tert-butylperoxide, 2,5-dimethyl-2,5-bis(tert-butyldioxy)hexenehydroperoxide, α-(iso-propylphenyl)-iso-propylhydroperoxide, tert-butylhydroperoxide, 1,1-bis(tert-butyldioxy)-3,3,5-trimethylcyclohexane, butyl-4,4-bis(tert-butyldioxy)valerate, cyclohexanone peroxide, 2,2′,5,5′-tetra(tert-butylperoxycarbonyl)benzophenone, 3,3′,4,4′-tetra(tert-butylperoxycarbonyl)benzophenone, 3,3′,4,4′-tetra(tert-amylperoxycarbonyl)benzophenone, 3,3′,4,4′-tetra(tert-hexylperoxycarbonyl)benzophenone, 3,3′-bis(tert-butylperoxycarbonyl)-4,4′-dicarboxybenzophenone, tert-butyl peroxybenzoate, and di-tert-butyl diperoxyisophthalate; quinones such as 9,10-anthraquinone, 1-chloroanthraquinone, 2-chloroanthraquinone, octamethylanthraquinone, and 1,2-benzanthraquinone; benzoin derivatives such as benzoin methyl, benzoin ethyl ether, α-methylbenzoin, and α-phenylbenzoin; alkylphenone-based compounds such as 2,2-dimethoxy-1,2-diphenylethan-1-one, 1-hydroxy-cyclohexyl-phenyl-ketone, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-[4-{4-(2-hydroxy-2-methyl-propionyl)benzyl}-phenyl]-2-methyl-propan-1-one, phenylglyoxylic acid methyl ester, 2-methyl-1-[4-(methylthio)phenyl]-2-morpholinopropan-1-one, 2-benzyl-2-dimethylamino-1-(4-morpholinophenyl)-1-butanone, and 2-dimethylamino-2-(4-methyl-benzyl)-1-(4-morpholin-4-yl-phenyl)-butan-1-one; acylphosphine oxide-based compounds such as bis(2,4,6-trimethylbenzoyl)-phenylphosphine oxide and 2,4,6-trimethylbenzoyl-diphenyl-phosphine oxide; and oxime ester-based compounds such as 2-(O-benzoyloxime)-1-[4-(phenylthio)phenyl]-1,2-octanedione and 1-(O-acetyloxime)-1-[9-ethyl-6-(2-methylbenzoyl)-9H-carbazol-3-yl]ethanone.

The photopolymerization initiator is commercially available, and specific examples thereof include IRGACURE (registered trademark) 651, 184, 500, 2959, 127, 754, 907, 369, 379, 379EG, 819, 819DW, 1800, 1870, 784, OXE01, OXE02, 250, 1173, MBF, 4265, and TPO (from BASF Japan Ltd.), KAYACURE (registered trademark) DETX, MBP, DMBI, EPA, and OA (from Nippon Kayaku Co., Ltd.), VICURE-10 and 55 (from STAUFFER Co. LTD), ESACURE (registered trademark) KIP 150, TZT, 1001, KTO 46, KBI, KL 200, KS 300, and EB 3, triazine-PMS, triazine A, and triazine B (from Nihon Siber Hegner K.K.), and Adeka Optomer N-1717, N-1414, and N-1606 (from ADEKA Corporation).

The above-described photopolymerization initiators can be used alone or in combination of two or more.

The content of the component (E) in the imprint material of the present invention is, for example, 0.1 to 30 phr, preferably 1 to 20 phr, and more preferably 1 to 8 phr, based on a total mass of the components (A), (B), (C), and (D), and the below-described component (F). If the content of the component (E) is less than 0.1 phr, sufficient curability cannot be achieved, leading to a deterioration of the patterning properties and a decrease in scratch resistance. As used herein, “phr” refers to the mass of, for example, the photopolymerization initiator as the component (E), relative to a total mass of 100 g of the components (A), (B), (C), (D), and (F).

[Component (F): Compound of Formula (5)]

The imprint material of the present invention may contain one or two compounds of formula (5) as a component (F):

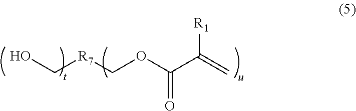

(wherein each R₁ is independently a hydrogen atom or a methyl group; R₇ is a tetravalent, pentavalent, or hexavalent organic group having a carbon atom number of 1 to 9 or a tetravalent, pentavalent, or hexavalent hydrocarbon group having a carbon atom number of 1 to 9, which has an ether bond in a main chain; t is 0 or 1; and u is an integer from 3 to 6).

Specific examples of the compound of formula (5) include pentaerythritol tri(meth)acrylate, pentaerythritol tetra(meth)acrylate, ditrimethylolpropane tetra(meth)acrylate, dipentaerythritol penta(meth)acrylate, and dipentaerythritol hexa(meth)acrylate.

The compound of formula (5) is commercially available, and specific examples thereof include KAYARAD (registered trademark) DPHA and PET-30 (from Nippon Kayaku Co., Ltd.), NK ester (registered trademark) A-TMMT, AD-TMP, A-9550, A-9530, and A-DPH (from Shin-Nakamura Chemical Co., Ltd.), Viscoat #400 (from Osaka Organic Chemical Industry Ltd.), ARONIX (registered trademark) M-402 and M-408 (from Toagosei Co., Ltd.), and KAYARAD (registered trademark) T-1420 (T) and D-310.

The content of the component (F) in the imprint material of the present invention is, for example, 1% by mass or more and 15% by mass or less, preferably 1% by mass or more and 10% by mass or less, based on a total mass of the components (A), (B), (C), (D), and (F). If the content of the component (F) is less than 1% by mass, the sensitivity of the composition during photoimprinting will decrease. On the other hand, if the content is over 15% by mass, the scratch resistance of the resulting film to the substrate will decrease.

[Component (G): Silicone Compound]

The imprint material of the present invention may contain a silicone compound as the component (G). The silicone compound as an optional component denotes a compound having a silicone skeleton (siloxane skeleton) in the molecule. In particular, the silicone compound preferably has a dimethyl silicone skeleton.

The silicone compound is commercially available, and specific examples thereof include BYK-302, BYK-307, BYK-322, BYK-323, BYK-330, BYK-333, BYK-370, BYK-375, BYK-378, BYK-UV 3500, and BYK-UV 3570 (from BYK-Chemie Japan K.K.), X-22-164, X-22-164AS, X-22-164A, X-22-164B, X-22-164C, X-22-164E, X-22-163, X-22-169AS, X-22-174DX, X-22-2426, X-22-9002, X-22-2475, X-22-4952, KF-643, X-22-343, X-22-2404, X-22-2046, and X-22-1602 (from Shin-Etsu Chemical Co., Ltd.), and Tego (registered trademark) Rad 2010, Rad 2011, Rad 2100, Rad 2200N, Rad 2250, Rad 2300, Rad 2500, and Rad 2700 (from Evonik Japan, Co., Ltd.).

The above-described silicone compounds can be used alone or in combination of two or more.

When the imprint material of the present invention contains a silicone compound as the component (G), the content of the component (G) is preferably 0.1 to 15 phr, and more preferably 1 to 10 phr, based on a total mass of the components (A), (B), (C), (D), and (F). If the content of the component (G) is less than 0.1 phr, a sufficiently low mold release force cannot be obtained even if the component (G) is added. On the other hand, if the content is over 15 phr, insufficient curing may occur, leading to a deterioration of the patterning properties.

[Component (H): Surfactant]

The imprint material of the present invention may contain a surfactant as the component (H). The surfactant as an optional component serves to adjust the film formability of the coating film to be obtained.

Examples of the surfactant include nonionic surfactants, including polyoxyethylene alkyl ethers such as polyoxyethylene lauryl ether, polyoxyethylene stearyl ether, polyoxyethylene cetyl ether, and polyoxyethylene oleyl ether; polyoxyethylene alkyl aryl ethers such as polyoxyethylene octylphenyl ether and polyoxyethylene nonylphenyl ether; polyoxyethylene-polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorosurfactants such as trade name EFTOP (registered trademark) EF301, EF303 and EF352 (from Mitsubishi Materials Electronic Chemicals Co., Ltd.), trade name MEGAFACE (registered trademark) F-171, F-173, F-477, F-486, F-554, F-556, R-08, R-30, R-30N, R-40, and R-40-LM (from DIC Corporation), Fluorad FC430 and FC431 (from Sumitomo 3M Co., Ltd.), AsahiGuard (registered trademark) AG710, Surflon (registered trademark)S-382, SC101, SC102, SC103, SC104, SC105, and SC106 (from Asahi Glass Co., Ltd.); and organosiloxane polymer KP341 (from Shin-Etsu Chemical Co., Ltd.).

The above-described surfactants can be used alone or in combination of two or more. When a surfactant is used, the content of the surfactant is preferably 0.01 to 40 phr, and more preferably 0.01 to 10 phr, based on a total mass of the components (A), (B), (C), (D), and (F).

[Component (1): Solvent]

The imprint material of the present invention may contain a solvent as the component (I). The solvent as an optional component serves to adjust the viscosity of the components (A), (B), (C), (D), and (F).

Examples of the solvent include toluene, p-xylene, o-xylene, styrene, ethylene glycol dimethyl ether, propylene glycol monomethyl ether, ethylene glycol monomethyl ether, propylene glycol monoethyl ether, ethylene glycol monoethyl ether, ethylene glycol monoisopropyl ether, ethylene glycol methyl ether acetate, propylene glycol monomethyl ether acetate, ethylene glycol ethyl ether acetate, diethylene glycol dimethyl ether, propylene glycol monobutyl ether, ethylene glycol monobutyl ether, diethylene glycol diethyl ether, dipropylene glycol monomethyl ether, diethylene glycol monomethyl ether, dipropylene glycol monoethyl ether, diethylene glycol monoethyl ether, triethylene glycol dimethyl ether, diethylene glycol monoethyl ether acetate, diethylene glycol, 1-octanol, ethylene glycol, hexylene glycol, diacetone alcohol, furfuryl alcohol, tetrahydrofurfuryl alcohol, propylene glycol, benzyl alcohol, 1,3-butanediol, 1,4-butanediol, 2,3-butanediol, γ-butyrolactone, acetone, methyl ethyl ketone, methyl isopropyl ketone, diethyl ketone, methyl isobutyl ketone, methyl n-butyl ketone, cyclohexanone, 2-heptanone, ethyl acetate, isopropyl acetate, n-propyl acetate, isobutyl acetate, n-butyl acetate, ethyl lactate, ethyl pyruvate, methanol, ethanol, isopropanol, tert-butanol, allyl alcohol, n-propanol, 2-methyl-2-butanol, isobutanol, n-butanol, 2-methyl-1-butanol, 1-pentanol, 2-methyl-1-pentanol, 2-ethylhexanol, trimethylene glycol, 1-methoxy-2-butanol, isopropyl ether, 1,4-dioxane, N,N-dimethylformamide, N,N-dimethylacetamide, N-methyl-2-pyrrolidone, 1,3-dimethyl-2-imidazolidinone, dimethyl sulfoxide, and N-cyclohexyl-2-pyrrolidine. The solvent is not particularly limited so long as it can adjust the viscosity of the components (A), (B), (C), (D), and (F).

The above-described solvents can be used alone or in combination of two or more. When a solvent is used, the solids content that is defined as the content of all components of the imprint material of the present invention, including the above-described components (A) to (D) and (F), and the below-described other additives, excluding the solvent as the component (I), is 20 to 80% by mass, and preferably 40 to 60% by mass, based on a total mass of the imprint material of the present invention.

[Other Additives]

The imprint material of the present invention can contain, as required, an epoxy compound, a photoacid generator, a photosensitizer, an ultraviolet absorber, an antioxidant, an adhesion aid, and a mold release improving agent, so long as they do not impair the effects of the present invention.

Examples of the epoxy compound include EPOLEAD (registered trademark) GT-401 and PB3600, CELLOXIDE (registered trademark) 2021P, 2000, and 3000, EHPE3150 and EHPE3150CE, CYCLOMER (registered trademark) M100 (from Daicel Corporation), EPICLON (registered trademark) 840, 840-S, N-660, and N-673-80M (from DIC Corporation).

Examples of the photoacid generator include IRGACURE (registered trademark) PAG103, PAG108, PAG121, PAG203, and CGI725 (from BASF Japan Ltd.), WPAG-145, WPAG-170, WPAG-199, WPAG-281, WPAG-336, and WPAG-367 (from Wako Pure Chemical Industries, Ltd.), TFE Triazine, TME-Triazine, MP-Triazine, Dimethoxytriazine, TS-91, and TS-01 (from Sanwa Chemical Co., Ltd.).

Examples of the photosensitizer include thioxanthene-based, xanthene-based, ketone-based, thiopyrylium salt-based, base styryl-based, merocyanine-based, 3-substituted coumarin-based, 3,4-substituted coumarin-based, cyanine-based, acridine-based, thiazine-based, phenothiazine-based, anthracene-based, coronene-based, benzanthracene-based, perylene-based, ketocoumarin-based, coumarin-based, and borate-based photosensitizers. These photosensitizers can be used alone or in combination of two or more. The absorption wavelength in the UV region can also be adjusted using the photosensitizer.

Examples of the ultraviolet absorber include TINUVIN (registered trademark) PS, 99-2, 109, 328, 384-2, 400, 405, 460, 477, 479, 900, 928, 1130, 111FDL, 123, 144, 152, 292, 5100, 400-DW, 477-DW, 99-DW, 123-DW, 5050, 5060, and 5151 (from BASF Japan Ltd.). These ultraviolet absorbers can be used alone or in combination of two or more. Using the ultraviolet absorber, the curing rate of the outermost surface of the film can be controlled during photocuring, which may improve the mold release properties.

Examples of the antioxidant include IRGANOX (registered trademark) 1010, 1035, 1076, 1135, and 1520L (from BASF Japan Ltd.). These antioxidants can be used alone or in combination of two or more. Using the antioxidant, yellowing of the film due to oxidation can be prevented.

Examples of the adhesion aid include 3-methacryloxypropyltrimethoxysilane and 3-acryloxypropyltrimethoxysilane. The adhesion of the film to the base material is improved using the adhesion aid. The content of the adhesion aid is preferably 5 to 50 phr, and more preferably 10 to 50 phr, based on a total mass of the components (A), (B), and (C).

Examples of the mold release improving agent include fluorine-containing compounds. Examples of the fluorine-containing compounds include R-5410, R-1420, M-5410, M-1420, E-5444, E-7432, A-1430, and A-1630 (from Daikin Industries, Ltd.), FOMBLIN (registered trademark) MT70 and MD40, Fluorolink (registered trademark) MD500, MD700, and AD1700 (from Solvay S.A.).

[Preparation of Imprint Material]

While the method for preparing the imprint material of the present invention is not particularly limited, the components (A), (B), (C), (D), and (E), as well as the optional components (F), (G), (H), and (I), as well as other additives, as desired, may be mixed such that the imprint material is in a homogeneous state. The order of mixing the components (A) to (I), as well as other additives, as desired, is not particularly limited so long as the homogeneous imprint material is obtained. Examples of the preparation method include a method in which predetermined proportions of the components (A), (B), (C), and (D) are mixed, and the mixture is further mixed with the component (E) as well as optionally the components (F), (G), (H), and (I), as appropriate, to form the homogeneous imprint material. Furthermore, examples of the preparation method also include a method in which other additives are further added and mixed, as required, in an appropriate stage of this preparation method.

[Photoimprinting and Pattern-Transferred Film]

The imprint material of the present invention may be applied onto the base material and photocured to form a desired coating film. Examples of coating methods include known or well-known methods, for example, a spin coating method, a dipping method, a flow coating method, an ink-jet method, a spraying method, a bar coating method, a gravure coating method, a slit coating method, a roll coating method, a transfer printing method, a brush coating method, a blade coating method, and an air knife coating method.

Examples of the base material to which the imprint material of the present invention is applied include substrates formed of silicon, glass having an indium tin oxide (ITO) film formed thereon (hereinafter abbreviated as “ITO substrate”), glass having a silicon nitride (SiN) film formed thereon (SiN substrate), glass having an indium zinc oxide (IZO) film formed thereon, polyethylene terephthalate (PET), triacetyl cellulose (TAC), acrylics, plastics, glass, quartz, ceramics, or the like. Flexible base materials are also usable, for example, base materials formed of triacetyl cellulose, polyethylene terephthalate, polymethyl methacrylate, cycloolefin (co)polymers, polyvinyl alcohol, polycarbonates, polystyrene, polyimides, polyamides, polyolefins, polypropylene, polyethylene, polyethylene naphthalate, or polyether sulfone, or copolymers formed using combinations of these polymers.

While the light source for curing the imprint material of the present invention is not particularly limited, examples thereof include a high-pressure mercury lamp, a low-pressure mercury lamp, an electrodeless lamp, a metal halide lamp, a KrF excimer laser, an ArF excimer laser, a F₂ excimer laser, an electron beam (EB), and extreme ultraviolet (EUV). As the wavelength, generally, G line at 436 nm, H line at 405 nm, I line at 365 nm, or GHI mixed line can be used. The exposure dose is preferably 30 to 2000 mJ/cm², and more preferably 30 to 1000 mJ/cm².

When a solvent as the above-described component (I) is used, a baking step may be applied to at least one of the coating film before light irradiation and the coating film after light irradiation, in order to evaporate the solvent. The baking device is not particularly limited, and may be any device that can bake the coating film using a hot plate, an oven, or a furnace, in an appropriate atmosphere, i.e., air, an inert gas such as nitrogen, or under vacuum. While the baking temperature is not particularly limited for the purpose of evaporating the solvent, it is, for example, 40 to 200° C.

While the apparatus for performing photoimprinting is not particularly limited so long as an intended pattern can be obtained, photoimprinting can be performed using, for example, a method in which a commercially available apparatus such as ST50 from Toshiba Machine Co., Ltd., Sindre (registered trademark) 60 from Obducat Technologies AB, or NM-0801HB from MEISYO KIKO Co., Ltd. is used to pressure-bond the base material and the mold with a roller, and the coating film after photocuring is released from the mold.

Examples of the mold material to be used for photoimprinting in the present invention include quartz, silicon, nickel, alumina, carbonyl silane, and glassy carbon, although the mold material is not particularly limited so long as an intended pattern can be obtained. To improve the mold release properties, the mold may be subjected to a mold release treatment to form a thin film of a fluorine-based compound or the like on the surface. Examples of the mold release agent to be used for the mold release treatment include Optool (registered trademark) HD and DSX from Daikin Industries, Ltd., although the mold release agent is not particularly limited so long as an intended pattern can be obtained.

The photoimprint pattern size is on the order of nanometers, and is specifically less than 1 micron.

### EXAMPLES

The present invention will be hereinafter described in more detail with reference to examples and comparative examples; however, the present invention is not limited to these examples.

[Preparation of Imprint Materials]

### Example 1

1 g of NK ester A-TMPT (hereinafter abbreviated as “A-TMPT”) (from Shin-Nakamura Chemical Co., Ltd.), 7.1 g of NK ester A-200 (hereinafter abbreviated as “A-200”) (from Shin-Nakamura Chemical Co., Ltd.), 1 g of NK ester A-GLY-9E (hereinafter abbreviated as “A-GLY-9E”) (from Shin-Nakamura Chemical Co., Ltd.), and 0.9 g of N,N′-dimethylacrylamide (hereinafter abbreviated as “DMAA”) (from KJ Chemicals Corporation) were mixed. To the mixture, 0.1 g (1 phr relative to a total mass of A-TMPT, A-200, A-GLY-9E, and DMAA) of IRGACURE (registered trademark) TPO (from Basf Japan Ltd.) (hereinafter abbreviated as “IRGACURE TPO”) was added to prepare an imprint material PNI-a1.

### Example 2

1.5 g of A-TMPT, 7.1 g of A-200, 0.5 g of KAYARAD DPEA-12 (hereinafter abbreviated as “DPEA-12”) (from Nippon Kayaku Co., Ltd.), and 0.9 g of DMAA were mixed. To the mixture, 0.1 g (1 phr relative to a total mass of A-TMPT, A-200, DPEA-12, and DMAA) of IRGACURE TPO was added to prepare an imprint material PNI-a2.

### Example 3

1 g of A-TMPT, 7 g of A-200, 1 g of NK ester ATM-35E (hereinafter abbreviated as “ATM-35E”) (from Shin-Nakamura Chemical Co., Ltd.), and 1 g of DMAA were mixed. To the mixture, 0.1 g (1 phr relative to a total mass of A-TMPT, A-200, ATM-35E, and DMAA) of IRGACURE TPO was added to prepare an imprint material PNI-a3.

### Example 4

0.9 g of A-TMPT, 7 g of A-200, 1 g of ATM-35E, 1 g of DMAA, and 0.1 g of KAYARAD DPHA (hereinafter abbreviated as “DPHA”) (from Nippon Kayaku Co., Ltd.) were mixed. To the mixture, 0.1 g (1 phr relative to a total mass of A-TMPT, A-200, ATM-35E, DMAA, and DPHA) of IRGACURE TPO was added to prepare an imprint material PNI-a4.

### Example 5

0.8 g of A-TMPT, 7 g of A-200, 1 g of ATM-35E, 1 g of DMAA, and 0.2 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a5.

### Example 6

0.8 g of A-TMPT, 7 g of A-200, 1 g of ATM-35E, 1 g of DMAA, and 0.2 g of DPHA were mixed. To the mixture, 0.5 g (5 phr relative to a total mass of A-TMPT, A-200, ATM-35E, DMAA, and DPHA) of BYK-UV3570 (from BYK-Chemie Japan K.K.) and 0.1 g (1 phr relative to a total mass of A-TMPT, A-200, ATM-35E, DMAA, and DPHA) of IRGACURE TPO were added to prepare an imprint material PNI-a6.

### Example 7

0.7 g of A-TMPT, 7 g of A-200, 1 g of ATM-35E, 1 g of DMAA, and 0.3 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a7.

### Example 8

0.6 g of A-TMPT, 7 g of A-200, 1 g of ATM-35E, 1 g of DMAA, and 0.4 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a8.

### Example 9

0.5 g of A-TMPT, 7 g of A-200, 1 g of ATM-35E, 1 g of DMAA, and 0.5 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a9.

### Example 10

1 g of A-TMPT, 7.1 g of A-200, 1 g of ATM-35E, and 0.9 g of DMAA were mixed. To the mixture, 0.1 g (1 phr relative to a total mass of A-TMPT, A-200, ATM-35E, and DMAA) of IRGACURE TPO was added to prepare an imprint material PNI-a10.

### Example 11

0.9 g of A-TMPT, 7.1 g of A-200, 1 g of ATM-35E, 0.9 g of DMAA, and 0.1 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a11.

### Example 12

0.8 g of A-TMPT, 7.1 g of A-200, 1 g of ATM-35E, 0.9 g of DMAA, and 0.2 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a12.

### Example 13

0.8 g of A-TMPT, 7.1 g of A-200, 1 g of ATM-35E, 0.9 g of DMAA, and 0.2 g of DPHA were mixed. To the mixture, 0.5 g (5 phr relative to a total mass of A-TMPT, A-200, ATM-35E, DMAA, and DPHA) of BYK-UV3570 (from BYK-Chemie Japan K.K.) and 0.1 g (1 phr relative to a total mass of A-TMPT, A-200, ATM-35E, DMAA, and DPHA) of IRGACURE TPO were added to prepare an imprint material PNI-a13.

### Example 14

0.7 g of A-TMPT, 7.1 g of A-200, 1 g of ATM-35E, 0.9 g of DMAA, and 0.3 g of DPHA were mixed. To the mixture, 0.5 g (5 phr relative to a total mass of A-TMPT, A-200, ATM-35E, DMAA, and DPHA) of BYK-UV3570 and 0.1 g (1 phr relative to a total mass of A-TMPT, A-200, ATM-35E, DMAA, and DPHA) of IRGACURE TPO were added to prepare an imprint material PNI-a14.

### Example 15

0.6 g of A-TMPT, 7.1 g of A-200, 1 g of ATM-35E, 0.9 g of DMAA, and 0.4 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a15.

### Example 16

0.5 g of A-TMPT, 7.1 g of A-200, 1 g of ATM-35E, 0.9 g of DMAA, and 0.5 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a16.

### Example 17

1 g of A-TMPT, 7 g of A-200, 1 g of ATM-35E, 0.9 g of DMAA, and 0.1 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a17.

### Example 18

1 g of A-TMPT, 7 g of A-200, 1 g of ATM-35E, 0.9 g of DMAA, and 0.1 g of DPHA were mixed. To the mixture, 0.1 g (1 phr relative to a total mass of A-TMPT, A-200, ATM-35E, DMAA, and DPHA) of BYK-UV3570 and 0.1 g (1 phr relative to a total mass of A-TMPT, A-200, ATM-35E, DMAA, and DPHA) of IRGACURE TPO were added to prepare an imprint material PNI-a18.

### Example 19

1 g of A-TMPT, 7 g of A-200, 1 g of ATM-35E, 0.9 g of DMAA, and 0.1 g of DPHA were mixed. To the mixture, 0.2 g (2 phr relative to a total mass of A-TMPT, A-200, ATM-35E, DMAA, and DPHA) of BYK-UV3570 and 0.1 g (1 phr relative to a total mass of A-TMPT, A-200, ATM-35E, DMAA, and DPHA) of IRGACURE TPO were added to prepare an imprint material PNI-a19.

### Example 20

1 g of A-TMPT, 7 g of A-200, 1 g of ATM-35E, 0.9 g of DMAA, and 0.1 g of DPHA were mixed. To the mixture, 0.3 g (3 phr relative to a total mass of A-TMPT, A-200, ATM-35E, DMAA, and DPHA) of BYK-UV3570 and 0.1 g (1 phr relative to a total mass of A-TMPT, A-200, ATM-35E, DMAA, and DPHA) of IRGACURE TPO were added to prepare an imprint material PNI-a20.

### Example 21

1 g of A-TMPT, 7 g of A-200, 1 g of ATM-35E, 0.9 g of DMAA, and 0.1 g of DPHA were mixed. To the mixture, 0.4 g (4 phr relative to a total mass of A-TMPT, A-200, ATM-35E, DMAA, and DPHA) of BYK-UV3570 and 0.1 g (1 phr relative to a total mass of A-TMPT, A-200, ATM-35E, DMAA, and DPHA) of IRGACURE TPO were added to prepare an imprint material PNI-a21.

### Example 22

1 g of A-TMPT, 7 g of A-200, 1 g of ATM-35E, 0.9 g of DMAA, and 0.1 g of DPHA were mixed. To the mixture, 0.5 g (5 phr relative to a total mass of A-TMPT, A-200, ATM-35E, DMAA, and DPHA) of BYK-UV3570 and 0.1 g (1 phr relative to a total mass of A-TMPT, A-200, ATM-35E, DMAA, and DPHA) of IRGACURE TPO were added to prepare an imprint material PNI-a22.

### Example 23

1 g of A-TMPT, 7.1 g of A-200, 0.9 g of ATM-35E, 0.9 g of DMAA, and 0.1 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a23.

### Example 24

1 g of A-TMPT, 7.1 g of A-200, 0.9 g of ATM-35E, 0.9 g of DMAA, and 0.1 g of DPHA were mixed. To the mixture, 0.5 g (5 phr relative to a total mass of A-TMPT, A-200, ATM-35E, DMAA, and DPHA) of BYK-UV3570 and 0.1 g (1 phr relative to a total mass of A-TMPT, A-200, ATM-35E, DMAA, and DPHA) of IRGACURE TPO were added to prepare an imprint material PNI-a24.

### Example 25

1 g of A-TMPT, 7.1 g of A-200, 0.8 g of ATM-35E, 0.9 g of DMAA, and 0.2 g of DPHA were mixed. To the mixture, 0.1 g (I phr relative to a total mass of A-TMPT, A-200, ATM-35E, DMAA, and DPHA) of IRGACURE TPO was added to prepare an imprint material PNI-a25.

### Example 26

1 g of A-TMPT, 7.1 g of A-200, 0.7 g of ATM-35E, 0.9 g of DMAA, and 0.3 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a26.

### Example 27

1 g of A-TMPT, 6.9 g of A-200, 1 g of ATM-35E, 1 g of DMAA, and 0.1 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a27.

### Example 28

1 g of A-TMPT, 7 g of A-200, 0.9 g of ATM-35E, 1 g of DMAA, and 0.1 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a28.

### Example 29

1 g of A-TMPT, 7 g of A-200, 0.8 g of ATM-35E, 1 g of DMAA, and 0.2 g of DPHA were mixed. To the mixture, 0.1 g (1 phr relative to a total mass of A-TMPT, A-200, ATM-35E, DMAA, and DPHA) of IRGACURE TPO was added to prepare an imprint material PNI-a29.

### Example 30

1 g of A-TMPT, 7 g of A-200, 0.7 g of ATM-35E, 1 g of DMAA, and 0.3 g of DPHA were mixed. To the mixture, 0.1 g (1 phr relative to a total mass of A-TMPT,

A-200, ATM-35E, DMAA, and DPHA) of IRGACURE TPO was added to prepare an imprint material PNI-a30.

### Example 31

1 g of A-TMPT, 7 g of A-200, 1 g of ATM-35E, 0.9 g of DMAA, and 0.1 g of KAYARAD PET30 (hereinafter abbreviated as “PET30”) (from Nippon Kayaku Co., Ltd.) were mixed. To the mixture, 0.1 g (1 phr relative to a total mass of A-TMPT, A-200, ATM-35E, DMAA, and DPHA) of IRGACURE TPO was added to prepare an imprint material PNI-a31.

### Example 32

0.1 g of A-TMPT, 7 g of A-200, 1.9 g of NK ester A-GLY-20E (hereinafter abbreviated as “A-GLY-20E”) (from Shin-Nakamura Chemical Co., Ltd.), and 1 g of DMAA were mixed. To the mixture, 0.1 g (1 phr relative to a total mass of A-TMPT, A-200, A-GLY-20E, and DMAA) of IRGACURE TPO was added to prepare an imprint material PNI-a32.

### Example 33

0.1 g of A-TMPT, 7 g of A-200, 1.9 g of NK ester A-GLY-20E, and 1 g of DMAA were mixed. To the mixture, 0.5 g (5 phr relative to a total mass of A-TMPT, A-200, A-GLY-20E, and DMAA) of BYK-UV3570 and 0.1 g (1 phr relative to a total mass of A-TMPT, A-200, A-GLY-20E, and DMAA) of IRGACURE TPO were added to prepare an imprint material PNI-a33.

### Example 34

0.1 g of A-TMPT, 6.8 g of A-200, 2.1 g of A-GLY-20E, and 1 g of DMAA were mixed. To the mixture, 0.1 g (1 phr relative to a total mass of A-TMPT, A-200, A-GLY-20E, and DMAA) of IRGACURE TPO was added to prepare an imprint material PNI-a34.

### Example 35

0.1 g of A-TMPT, 6.8 g of A-200, 2.1 g of A-GLY-20E, and 1 g of DMAA were mixed. To the mixture, 0.5 g (5 phr relative to a total mass of A-TMPT, A-200, A-GLY-20E, and DMAA) of BYK-UV3570 and 0.1 g (1 phr relative to a total mass of A-TMPT, A-200, A-GLY-20E, and DMAA) of IRGACURE TPO were added to prepare an imprint material PNI-a35.

### Example 36

0.2 g of A-TMPT, 6.8 g of A-200, 2 g of A-GLY-20E, and 1 g of DMAA were mixed. To the mixture, 0.1 g (1 phr relative to a total mass of A-TMPT, A-200, A-GLY-20E, and DMAA) of IRGACURE TPO was added to prepare an imprint material PNI-a36.

### Example 37

0.2 g of A-TMPT, 6.8 g of A-200, 2 g of A-GLY-20E, and 1 g of DMAA were mixed. To the mixture, 0.5 g (5 phr relative to a total mass of A-TMPT, A-200, A-GLY-20E, and DMAA) of BYK-UV3570 and 0.1 g (1 phr relative to a total mass of A-TMPT, A-200, A-GLY-20E, and DMAA) of IRGACURE TPO were added to prepare an imprint material PNI-a37.

### Example 38

0.2 g of A-TMPT, 6.8 g of A-200, 2 g of A-GLY-20E, and 1 g of DMAA were mixed. To the mixture, 0.2 g (2 phr relative to a total mass of A-TMPT, A-200, A-GLY-20E, and DMAA) of Tego (registered trademark) Rad 2200N (hereinafter abbreviated as “Tego Rad 2200N”) (from Evonik Japan, Co., Ltd.), 0.1 g (1 phr relative to a total mass of A-TMPT, A-200, A-GLY-20E, and DMAA) of BYK-UV3570, and 0.1 g (1 phr relative to a total mass of A-TMPT, A-200, ATM-35E, and DMAA) of IRGACURE TPO were added to prepare an imprint material PNI-a38.

### Example 39

0.2 g of A-TMPT, 6.8 g of A-200, 2 g of A-GLY-20E, and 1 g of DMAA were mixed. To the mixture, 0.1 g (1 phr relative to a total mass of A-TMPT, A-200, A-GLY-20E, and DMAA) of Tego Rad 2200N, 0.2 g (2 phr relative to a total mass of A-TMPT, A-200, A-GLY-20E, and DMAA) of BYK-UV3570, and 0.1 g (1 phr relative to a total mass of A-TMPT, A-200, ATM-35E, and DMAA) of IRGACURE TPO were added to prepare an imprint material PNI-a39.

### Example 40

0.2 g of A-TMPT, 6.8 g of A-200, 2 g of A-GLY-20E, and 1 g of DMAA were mixed. To the mixture, 0.05 g (0.5 phr relative to a total mass of A-TMPT, A-200, A-GLY-20E, and DMAA) of Tego Rad 2200N, 0.25 g (2.5 phr relative to a total mass of A-TMPT, A-200, A-GLY-20E, and DMAA) of BYK-UV3570, and 0.1 g (1 phr relative to a total mass of A-TMPT, A-200, ATM-35E, and DMAA) of IRGACURE TPO were added to prepare an imprint material PNI-a40.

### Example 41

0.1 g of A-TMPT, 6.8 g of A-200, 2 g of A-GLY-20E, 1 g of DMAA, and 0.1 g of DPHA were mixed. To the mixture, 0.1 g (1 phr relative to a total mass of A-TMPT, A-200, A-GLY-20E, DMAA, and DPHA) of IRGACURE TPO was added to prepare an imprint material PNI-a41.

### Example 42

0.1 g of A-TMPT, 6.8 g of A-200, 2 g of A-GLY-20E, 1 g of DMAA, and 0.1 g of DPHA were mixed. To the mixture, 0.5 g (5 phr relative to a total mass of A-TMPT, A-200, A-GLY-20E, DMAA, and DPHA) of BYK-UV3570 and 0.1 g (1 phr relative to a total mass of A-TMPT, A-200, A-GLY-20E, DMAA, and DPHA) of IRGACURE TPO were added to prepare an imprint material PNI-a42.

### Example 43

0.2 g of A-TMPT, 6.9 g of A-200, 2 g of A-GLY-20E, and 0.9 g of DMAA were mixed. To the mixture, 0.4 g (4 phr relative to a total mass of A-TMPT, A-200, A-GLY-20E, and DMAA) of BYK-UV3570 and 0.1 g (1 phr relative to a total mass of A-TMPT, A-200, A-GLY-20E, and DMAA) of IRGACURE TPO were added to prepare an imprint material PNI-a43.

### Example 44

0.2 g of A-TMPT, 6.9 g of A-200, 2 g of A-GLY-20E, and 0.9 g of DMAA were mixed. To the mixture, 0.5 g (5 phr relative to a total mass of A-TMPT, A-200, A-GLY-20E, and DMAA) of BYK-UV3570 and 0.1 g (1 phr relative to a total mass of A-TMPT, A-200, A-GLY-20E, and DMAA) of IRGACURE TPO were added to prepare an imprint material PNI-a44.

### Example 45

0.2 g of A-TMPT, 6.9 g of A-200, 2 g of A-GLY-20E, and 0.9 g of DMAA were mixed. To the mixture, 0.6 g (6 phr relative to a total mass of A-TMPT, A-200, A-GLY-20E, and DMAA) of BYK-UV3570 and 0.1 g (1 phr relative to a total mass of A-TMPT, A-200, A-GLY-20E, and DMAA) of IRGACURE TPO were added to prepare an imprint material PNI-a45.

### Example 46

1 g of A-TMPT, 7 g of A-200, 1 g of ATM-35E, 0.9 g of DMAA, and 0.1 g of DPHA were mixed. To the mixture, 0.3 g (3 phr relative to a total mass of A-TMPT, A-200, ATM-35E, DMAA, and DPHA) of Tego (registered trademark) Rad 2300 (hereinafter abbreviated as “Tego Rad 2300”) (from Evonik Japan, Co., Ltd.) and 0.1 g (1 phr relative to a total mass of A-TMPT, A-200, ATM-35E, DMAA, and DPHA) of IRGACURE TPO were added to prepare an imprint material PNI-a46.

### Example 47

1 g of A-TMPT, 7 g of A-200, 1 g of ATM-35E, 0.9 g of DMAA, and 0.1 g of DPHA were mixed. To the mixture, 0.4 g (4 phr relative to a total mass of A-TMPT, A-200, ATM-35E, DMAA, and DPHA) of Tego Rad 2300 and 0.1 g (1 phr relative to a total mass of A-TMPT, A-200, ATM-35E, DMAA, and DPHA) of IRGACURE TPO were added to prepare an imprint material PNI-a47.

### Example 48

1 g of A-TMPT, 7 g of A-200, 1 g of ATM-35E, 0.9 g of DMAA, and 0.1 g of DPHA were mixed. To the mixture, 0.5 g (5 phr relative to a total mass of A-TMPT, A-200, ATM-35E, DMAA, and DPHA) of Tego Rad 2300 and 0.1 g (1 phr relative to a total mass of A-TMPT, A-200, ATM-35E, DMAA, and DPHA) of IRGACURE TPO were added to prepare an imprint material PNI-a48.

### Example 49

1 g of A-TMPT, 7 g of A-200, 1 g of ATM-35E, 0.9 g of DMAA, and 0.1 g of DPHA were mixed. To the mixture, 0.6 g (6 phr relative to a total mass of A-TMPT, A-200, ATM-35E, DMAA, and DPHA) of Tego Rad 2300 and 0.1 g (1 phr relative to a total mass of A-TMPT, A-200, ATM-35E, DMAA, and DPHA) of IRGACURE TPO were added to prepare an imprint material PNI-a49.

### Example 50

1.1 g of A-TMPT, 7 g of A-200, 1 g of ATM-35E, and 0.9 g of DMAA were mixed. To the mixture, 0.3 g (3 phr relative to a total mass of A-TMPT, A-200, ATM-35E, and DMAA) of Tego Rad 2300 and 0.1 g (1 phr relative to a total mass of A-TMPT, A-200, ATM-35E, and DMAA) of IRGACURE TPO were added to prepare an imprint material PNI-a50.

### Example 51

1 g of A-TMPT, 7.1 g of A-200, 1 g of ATM-35E, and 0.9 g of DMAA were mixed. To the mixture, 0.3 g (3 phr relative to a total mass of A-TMPT, A-200, ATM-35E, and DMAA) of Tego Rad 2300 and 0.1 g (1 phr relative to a total mass of A-TMPT, A-200, ATM-35E, and DMAA) of IRGACURE TPO were added to prepare an imprint material PNI-a51.

### Example 52

1.05 g of A-TMPT, 7 g of A-200, 1 g of ATM-35E, 0.9 g of DMAA, and 0.05 g of DPHA were mixed. To the mixture, 0.3 g (3 phr relative to a total mass of A-TMPT, A-200, ATM-35E, DMAA, and DPHA) of Tego Rad 2300 and 0.1 g (1 phr relative to a total mass of A-TMPT, A-200, ATM-35E, DMAA, and DPHA) of IRGACURE TPO were added to prepare an imprint material PNI-a52.

### Example 53

1 g of A-TMPT, 7.05 g of A-200, 1 g of ATM-35E, 0.9 g of DMAA, and 0.05 g of DPHA were mixed. To the mixture, 0.3 g (3 phr relative to a total mass of A-TMPT, A-200, ATM-35E, DMAA, and DPHA) of Tego Rad 2300 and 0.1 g (1 phr relative to a total mass of A-TMPT, A-200, ATM-35E, DMAA, and DPHA) of IRGACURE TPO were added to prepare an imprint material PNI-a53.

### Example 54

1 g of A-TMPT, 7.1 g of A-200, 1 g of ATM-35E, and 0.9 g of DMAA were mixed. To the mixture, 0.1 g (1 phr relative to a total mass of A-TMPT, A-200, ATM-35E, and DMAA) of Tego Rad 2300, 0.2 g (2 phr relative to a total mass of A-TMPT, A-200, ATM-35E, and DMAA) of BYK-UV3570, and 0.1 g (1 phr relative to a total mass of A-TMPT, A-200, ATM-35E, and DMAA) of IRGACURE TPO were added to prepare an imprint material PNI-a54.

### Example 55

1 g of A-TMPT, 7.1 g of A-200, 1 g of ATM-35E, and 0.9 g of DMAA were mixed. To the mixture, 0.2 g (2 phr relative to a total mass of A-TMPT, A-200, ATM-35E, and DMAA) of Tego Rad 2300, 0.1 g (1 phr relative to a total mass of A-TMPT, A-200, ATM-35E, and DMAA) of BYK-UV3570, and 0.1 g (1 phr relative to a total mass of A-TMPT, A-200, ATM-35E, and DMAA) of IRGACURE TPO were added to prepare an imprint material PNI-a55.

### Example 56

1 g of A-TMPT, 7.1 g of A-200, 1 g of ATM-35E, and 0.9 g of DMAA were mixed. To the mixture, 0.01 g (0.1 phr relative to a total mass of A-TMPT, A-200, ATM-35E, and DMAA) of Tego Rad 2300, 0.31 g (3.1 phr relative to a total mass of A-TMPT, A-200, ATM-35E, and DMAA) of BYK-UV3570, and 0.1 g (1 phr relative to a total mass of A-TMPT, A-200, ATM-35E, and DMAA) of IRGACURE TPO were added to prepare an imprint material PNI-a56.

### Example 57

1 g of A-TMPT, 7.1 g of A-200, 1 g of ATM-35E, and 0.9 g of DMAA were mixed. To the mixture, 0.03 g (0.3 phr relative to a total mass of A-TMPT, A-200, ATM-35E, and DMAA) of Tego Rad 2300, 0.28 g (2.8 phr relative to a total mass of A-TMPT, A-200, ATM-35E, and DMAA) of BYK-UV3570, and 0.1 g (1 phr relative to a total mass of A-TMPT, A-200, ATM-35E, and DMAA) of IRGACURE TPO were added to prepare an imprint material PNI-a57.

### Example 58

1 g of A-TMPT, 7.1 g of A-200, 1 g of ATM-35E, and 0.9 g of DMAA were mixed. To the mixture, 0.05 g (0.5 phr relative to a total mass of A-TMPT, A-200, ATM-35E, and DMAA) of Tego Rad 2300, 0.25 g (2.5 phr relative to a total mass of A-TMPT, A-200, ATM-35E, and DMAA) of BYK-UV3570, and 0.1 g (1 phr relative to a total mass of A-TMPT, A-200, ATM-35E, and DMAA) of IRGACURE TPO were added to prepare an imprint material PNI-a58.

### Example 59

1 g of A-TMPT, 7 g of A-200, 1 g of ATM-35E, 0.9 g of DMAA, and 0.1 g of DPHA were mixed. To the mixture, 0.01 g (0.1 phr relative to a total mass of A-TMPT, A-200, ATM-35E, DMAA, and DPHA) of Tego Rad 2300, 0.31 g (3.1 phr relative to a total mass of A-TMPT, A-200, ATM-35E, DMAA, and DPHA) of BYK-UV3570, and 0.1 g (1 phr relative to a total mass of A-TMPT, A-200, ATM-35E, DMAA, and DPHA) of IRGACURE TPO were added to prepare an imprint material PNI-a59.

### Example 60

1 g of A-TMPT, 7 g of A-200, 1 g of ATM-35E, 0.9 g of DMAA, and 0.1 g of DPHA were mixed. To the mixture, 0.03 g (0.3 phr relative to a total mass of A-TMPT, A-200, ATM-35E, DMAA, and DPHA) of Tego Rad 2300, 0.28 g (2.8 phr relative to a total mass of A-TMPT, A-200, ATM-35E, DMAA, and DPHA) of BYK-UV3570, and 0.1 g (1 phr relative to a total mass of A-TMPT, A-200, ATM-35E, DMAA, and DPHA) of IRGACURE TPO were added to prepare an imprint material PNI-a60.

### Example 61

1 g of A-TMPT, 7 g of A-200, 1 g of ATM-35E, 0.9 g of DMAA, and 0.1 g of DPHA were mixed. To the mixture, 0.05 g (0.5 phr relative to a total mass of A-TMPT, A-200, ATM-35E, DMAA, and DPHA) of Tego Rad 2300, 0.25 g (2.5 phr relative to a total mass of A-TMPT, A-200, ATM-35E, DMAA, and DPHA) of BYK-UV3570, and 0.1 g (1 phr relative to a total mass of A-TMPT, A-200, ATM-35E, DMAA, and DPHA) of IRGACURE TPO were added to prepare an imprint material PNI-a61.

### Example 62

1 g of A-TMPT, 7 g of A-200, 1 g of ATM-35E, 0.9 g of DMAA, and 0.1 g of DPHA were mixed. To the mixture, 0.1 g (1 phr relative to a total mass of A-TMPT, A-200, ATM-35E, DMAA, and DPHA) of Tego Rad 2300, 0.2 g (2 phr relative to a total mass of A-TMPT, A-200, ATM-35E, DMAA, and DPHA) of BYK-UV3570, and 0.1 g (1 phr relative to a total mass of A-TMPT, A-200, ATM-35E, DMAA, and DPHA) of IRGACURE TPO were added to prepare an imprint material PNI-a62.

### Example 63

1 g of A-TMPT, 7 g of A-200, 1 g of ATM-35E, 0.9 g of DMAA, and 0.1 g of DPHA were mixed. To the mixture, 0.125 g (1 phr relative to a total mass of A-TMPT, A-200, ATM-35E, DMAA, and DPHA) of FOMBLIN (registered trademark) MT70 (hereinafter abbreviated as “MT70”) (from Solvay S.A.) and 0.1 g (1 phr relative to a total mass of A-TMPT, A-200, ATM-35E, DMAA, and DPHA) of IRGACURE TPO were added to prepare an imprint material PNI-a63.

### Example 64

1 g of A-TMPT, 7 g of A-200, 1 g of ATM-35E, 0.9 g of DMAA, and 0.1 g of DPHA were mixed. To the mixture, 0.25 g (2 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a64.

### Example 65

1 g of A-TMPT, 7 g of A-200, 1 g of ATM-35E, 0.9 g of DMAA, and 0.1 g of DPHA were mixed. To the mixture, 0.375 g (3 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a65.

### Example 66

A portion of methyl ethyl ketone contained in MT70 was distilled using an evaporator to adjust the residual content of methyl ethyl ketone to 6.8% by mass to obtain MT70-A. Then, 0.2146 g (2 phr relative to a total mass of A-TMPT, A-200, ATM-35E, DMAA, and DPHA) of MT70-A was added to the imprint material PNI-a17 obtained in Example 17 to prepare an imprint material PNI-a66.

### Example 67

1 g of A-TMPT, 7.1 g of A-200, 1 g of ATM-35E, 0.8 g of DMAA, and 0.1 g of DPHA were mixed. To the mixture, 0.25 g (2 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a67.

### Example 68

1 g of A-TMPT, 7.2 g of A-200, 1 g of ATM-35E, 0.7 g of DMAA, and 0.1 g of DPHA were mixed. To the mixture, 0.25 g (2 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a68.

### Example 69

1 g of A-TMPT, 7.3 g of A-200, 1 g of ATM-35E, 0.6 g of DMAA, and 0.1 g of DPHA were mixed. To the mixture, 0.25 g (2 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a69.

### Example 70

1 g of A-TMPT, 7.4 g of A-200, 1 g of ATM-35E, 0.5 g of DMAA, and 0.1 g of DPHA were mixed. To the mixture, 0.25 g (2 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a70.

### Example 71

1 g of A-TMPT, 7.5 g of A-200, 1 g of ATM-35E, 0.4 g of DMAA, and 0.1 g of DPHA were mixed. To the mixture, 0.25 g (2 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a71.

### Example 72

1 g of A-TMPT, 7.6 g of A-200, 1 g of ATM-35E, 0.3 g of DMAA, and 0.1 g of DPHA were mixed. To the mixture, 0.25 g (2 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a72.

### Example 73

1 g of A-TMPT, 7.7 g of A-200, 1 g of ATM-35E, 0.2 g of DMAA, and 0.1 g of DPHA were mixed. To the mixture, 0.25 g (2 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a73.

### Example 74

1 g of A-TMPT, 7.8 g of A-200, 1 g of ATM-35E, 0.1 g of DMAA, and 0.1 g of DPHA were mixed. To the mixture, 0.25 g (2 phr relative to a total mass of A-TMPT, A-200, ATM-35E, DMAA, and DPHA) of MT70 and 0.1 g (1 phr relative to a total mass of A-TMPT, A-200, ATM-35E, DMAA, and DPHA) of IRGACURE TPO were added to prepare an imprint material PNI-a74.

### Comparative Example 1

10 g of A-TMPT and 0.1 g (1 phr relative to A-TMPT) of IRGACURE TPO were mixed to prepare an imprint material PNI-b1.

### Comparative Example 2

10 g of PET30 and 0.1 g (1 phr relative to A-TMPT) of IRGACURE TPO were mixed to prepare an imprint material PNI-b2.

### Comparative Example 3

9 g of A-TMPT and 1 g of DMAA were mixed, and 0.1 g (1 phr relative to a total mass of A-TMPT and DMAA) of IRGACURE TPO was added to the mixture to prepare an imprint material PNI-b3.

### Comparative Example 4

6.5 g of A-200 and 3.5 g of NK Economer A-1000PER (hereinafter abbreviated as “A-1000PER”) (from Shin-Nakamura Chemical Co., Ltd.) were mixed, and 0.1 g (1 phr relative to a total mass of A-200 and A-1000PER) of IRGACURE TPO was added to the mixture to prepare an imprint material PNI-b4.

### Comparative Example 5

8.7 g of A-200 and 1.3 g of DMAA were mixed, and 0.1 g (1 phr relative to a total mass of A-200 and DMAA) of IRGACURE TPO was added to the mixture to prepare an imprint material PNI-b5.

### Comparative Example 6

3.0 g of PET30, 6 g of A-200, and 1 g of DMAA were mixed, and 0.5 g (5 phr relative to a total mass of PET30, A-200, and DMAA) of BYK-UV3570 and 0.1 g (1 phr relative to a total mass of PET30, A-200, and DMAA) of IRGACURE TPO were added to the mixture to prepare an imprint material PNI-b6

### Comparative Example 7

3.0 g of PET30, 6 g of A-200, and 1 g of DMAA were mixed, and 0.1 g (1 phr relative to a total mass of PET30, A-200 and DMAA) of IRGACURE TPO was added to the mixture to prepare an imprint material PNI-b7.

[Mold Release Treatment of Mold]

A moth-eye pattern mold made of nickel having a pitch of 250 nm and a height of 250 nm (from InnoX Co., Ltd.) and a silicon wafer were immersed in a solution prepared by diluting Optool (registered trademark) DSX (from Daikin Industries, LTD.) with Novec (registered trademark) HFE-7100 (hydrofluoroether from Sumitomo 3M Co., Ltd.) (hereinafter abbreviated as “Novec HFE-7100”) to 0.1% by mass, and treated for 1 hour using a high-temperature high-humidity apparatus at a temperature of 90° C. and a humidity of 90 RH %. The mold and the silicon wafer were rinsed with Novec HFE-7100 and then dried with air.

[Photoimprinting]

Each of the imprint materials obtained in Examples 1 to 74 and Comparative Examples 1 to 7 was applied onto a 60-μm-thick triacetyl cellulose film (FUJITAC (registered trademark) from Fujifilm Corporation was used) (hereinafter abbreviated as “TAC film”), using a bar coater (Full Automatic Film Applicator KT-AB3120 from Cotec Corporation), and the coating film on the TAC film was pressure-bonded to the above-described mold release-treated moth-eye pattern mold with a roller. The coating film was subsequently photocured by being exposed to light at 256 mJ/cm² from the TAC film side, using an electrodeless uniform irradiation device (QRE-4016A from Ore Manufacturing Co., Ltd.), and then the TAC film was released from the moth-eye pattern mold to obtain a cured coating film having a projection-and-recess shape of the moth-eye pattern mold transferred thereon.

[Adhesion Test]

The obtained cured coating film was subjected to an adhesion test with the TAC film. The adhesion test was performed using the following procedures in accordance with JIS K5400.

Initially, lattice-like cuts were made in the cured coating film using a cutter to reach the TAC film to form 100 squares at intervals of 1 mm. A cellophane adhesive tape having a length of about 50 mm was adhered to the lattice, and then instantaneously peeled off at an angle of 90° to the film surface. The squares after peeling of the tape were observed. The number of squares that were not peeled off in the 100 squares was defined as ×, and the adhesion was evaluated as ×/100. This adhesion test was repeated three times, and the average value of the evaluations was calculated.

[Steel Wool Scratch Test]

The obtained cured coating film was subjected to a steel wool scratch test. A tester from Daiei Kagaku Seiki Mfg. Co., Ltd. was used, and #0000 steel wool was used. The load per unit area was set to 81.5 g/cm², and the steel wool was reciprocated 10 times. The number of scratches after scratching was then examined. This scratch test was repeated three times, and the average number of scratches after scratching was calculated. The average number of scratches was evaluated as shown below:

0 to 1 scratch: A

2 to 5 scratches: B

6 to 10 scratches: C

11 or more scratches: D

[Surface Wiping Resistance Test]

The back side of the surface of the obtained cured coating film having the projection-and-recess shape transferred thereon was affixed to a black acrylic plate, and the surface having the projection-and-recess shape transferred thereon was scrubbed with BEMCOT M-1 (from Asahi Kasei Fibers Corporation) in one direction under a load of 4 kg. The cured coating film was subsequently irradiated with a fluorescent lamp from the side having the projection-and-recess shape, and the presence or absence of haze was visually examined from an oblique angle of 30° to the cured coating film. As used herein, “haze” refers to scattering of light that occurs in a position where projections collapsed in the projection-and-recess shape.

The results are shown in Tables 1 to 4.

[Confirmation of Imprintability]

A moth-eye pattern mold made of nickel having a pitch of 250 nm and a height of 300 nm (from InnoX Co., Ltd.) was subjected to a mold release treatment in accordance with the above-described method, and a cured coating film was obtained by subjecting each of the imprint materials obtained in Examples 63 to 74 to photoimprinting as described above. The presence or absence of peeling or cracking of the pattern on the cured coating film was observed with an industrial microscope ECLIPSE L150 (from Nikon Corporation). The results are shown in Table 5.

TABLE 1

| | | Scratch | Presence or Absence |
|---|---|---|---|
| | Adhesion | Resistance | of Haze |
| Example 1 | 96/100 | B | Absent |
| Example 2 | 95/100 | B | Absent |
| Example 3 | 96/100 | B | Absent |
| Example 4 | 100/100 | B | Absent |
| Example 5 | 100/100 | B | Absent |
| Example 6 | 100/100 | A | Absent |
| Example 7 | 100/100 | B | Absent |
| Example 8 | 100/100 | B | Absent |
| Example 9 | 100/100 | B | Absent |
| Example 10 | 97/100 | B | Absent |
| Example 11 | 100/100 | B | Absent |
| Example 12 | 100/100 | B | Absent |
| Example 13 | 100/100 | A | Absent |
| Example 14 | 100/100 | A | Absent |
| Example 15 | 100/100 | B | Absent |
| Example 16 | 100/100 | B | Absent |
| Example 17 | 100/100 | B | Absent |
| Example 18 | 100/100 | A | Absent |
| Example 19 | 100/100 | A | Absent |
| Example 20 | 100/100 | A | Absent |
| Example 21 | 100/100 | A | Absent |
| Example 22 | 100/100 | A | Absent |
| Example 23 | 100/100 | B | Absent |
| Example 24 | 100/100 | A | Absent |
| Example 25 | 100/100 | B | Absent |

TABLE 2

| | | Scratch | Presence or Absence |
|---|---|---|---|
| | Adhesion | Resistance | of Haze |
| Example 26 | 100/100 | B | Absent |
| Example 27 | 100/100 | B | Absent |
| Example 28 | 100/100 | B | Absent |
| Example 29 | 100/100 | B | Absent |
| Example 30 | 100/100 | B | Absent |
| Example 31 | 97/100 | B | Absent |
| Example 32 | 97/100 | B | Absent |
| Example 33 | 96/100 | A | Absent |
| Example 34 | 96/100 | A | Absent |
| Example 35 | 95/100 | B | Absent |
| Example 36 | 97/100 | A | Absent |
| Example 37 | 95/100 | A | Absent |
| Example 38 | 97/100 | A | Absent |
| Example 39 | 96/100 | A | Absent |
| Example 40 | 96/100 | A | Absent |
| Example 41 | 98/100 | A | Absent |
| Example 42 | 98/100 | A | Absent |
| Example 43 | 99/100 | A | Absent |
| Example 44 | 99/100 | A | Absent |
| Example 45 | 96/100 | A | Absent |
| Example 46 | 96/100 | A | Absent |
| Example 47 | 96/100 | A | Absent |
| Example 48 | 97/100 | A | Absent |
| Example 49 | 97/100 | A | Absent |
| Example 50 | 100/100 | A | Absent |

TABLE 3

| | | Scratch | Presence or Absence |
|---|---|---|---|
| | Adhesion | Resistance | of Haze |
| Example 51 | 100/100 | A | Absent |
| Example 52 | 97/100 | A | Absent |
| Example 53 | 95/100 | A | Absent |
| Example 54 | 100/100 | B | Absent |
| Example 55 | 99/100 | B | Absent |
| Example 56 | 99/100 | B | Absent |
| Example 57 | 98/100 | B | Absent |
| Example 58 | 99/100 | B | Absent |
| Example 59 | 100/100 | B | Absent |
| Example 60 | 100/100 | B | Absent |
| Example 61 | 99/100 | B | Absent |
| Example 62 | 98/100 | B | Absent |
| Example 63 | 100/100 | A | Absent |
| Example 64 | 100/100 | A | Absent |
| Example 65 | 100/100 | A | Absent |
| Example 66 | 100/100 | A | Absent |
| Example 67 | 100/100 | A | Absent |
| Example 68 | 100/100 | A | Absent |
| Example 69 | 100/100 | A | Absent |
| Example 70 | 100/100 | A | Absent |
| Example 71 | 99/100 | A | Absent |
| Example 72 | 99/100 | A | Absent |
| Example 73 | 98/100 | A | Absent |
| Example 74 | 96/100 | A | Absent |

TABLE 4

| | | Scratch | Presence or Absence |
|---|---|---|---|
| | Adhesion | Resistance | of Haze |
| Comparative Example 1 | 0/100 | D | Absent |
| Comparative Example 2 | 0/100 | D | Absent |
| Comparative Example 3 | 20/100 | D | Absent |
| Comparative Example 4 | 0/100 | A | Present |
| Comparative Example 5 | 99/100 | C | Present |
| Comparative Example 6 | 23/100 | D | Absent |
| Comparative Example 7 | 54/100 | D | Absent |

TABLE 5

| | Cracking of Pattern | Peeling of Pattern |
|---|---|---|
| Example 63 | Absent | Absent |
| Example 64 | Absent | Absent |
| Example 65 | Absent | Absent |
| Example 66 | Absent | Absent |
| Example 67 | Absent | Absent |
| Example 68 | Absent | Absent |
| Example 69 | Absent | Absent |
| Example 70 | Absent | Absent |
| Example 71 | Absent | Absent |
| Example 72 | Absent | Absent |
| Example 73 | Absent | Absent |
| Example 74 | Absent | Absent |

The results shown in Tables 1 to 3 confirmed that all the cured coating films obtained using the imprint materials prepared in Examples 1 to 74 had excellent adhesion to the TAC film, had scratch resistance because the number of scratches formed after the steel wool scratch test was small, i.e., 0 to 5, and had high wiping resistance because a collapse of projections did not occur even when the surface having the projection-and-recess shape transferred thereon was scrubbed under high load. On the other hand, the results shown in Table 4 confirmed that the cured coating films obtained using the imprint materials prepared in Comparative Examples 1 to 3, 6 and 7 generated many scratches after the steel wool scratch test, and lacked adhesion to the TAC film. Furthermore, in the cured coating films obtained using the imprint materials prepared in Comparative Examples 4 and 5, a collapse of projections occurred when the surface having the projection-and-recess shape transferred thereon was scrubbed under high load, and haze was generated. The foregoing shows that the cured coating films obtained using the imprint materials of the present invention have excellent adhesion to the substrate, scratch resistance, and excellent wiping resistance.

1. An imprint material comprising a component (A), a component (B), a component (C), a component (D), and a component (E):
(A) a compound of formula (1);
(B) a compound of formula (2);
(C) a compound of formula (3);
(D) a compound of formula (4); and
(E) a photopolymerization initiator: 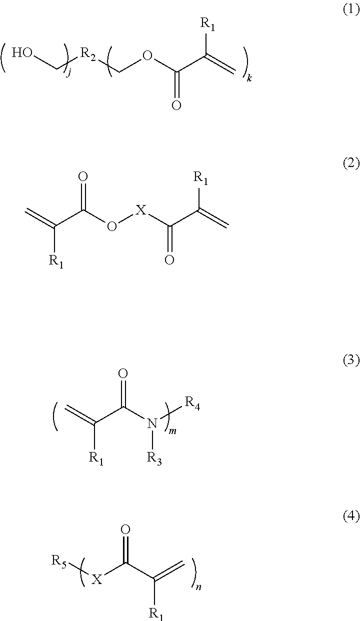
wherein each R₁ is independently a hydrogen atom or a methyl group; R₂ is a divalent or trivalent hydrocarbon group having a carbon atom number of 1 to 5; j is 0 or 1; k is 2 or 3; X is a divalent linking group having an ethylene oxide unit and/or a propylene oxide unit; R₃ is a hydrogen atom or a C₁₋₃ alkyl group; m is 1 or 2; R₅ is a trivalent, tetravalent, pentavalent, or hexavalent organic group having a carbon atom number of 3 to 10, which optionally has at least one hetero atom; n is an integer from 3 to 6;
where m is 1, R₄ is a C₁₋₁₂ alkyl group optionally substituted with at least one substituent selected from the group consisting of a hydroxy group, a carboxy group, an acetyl group, an amino group in which one or two hydrogen atoms are optionally substituted with a methyl group or methyl groups, a sulfo group, and a C₁₋₄ alkoxy group; and
where m is 2, R₄ is a C₁₋₁₂ alkylene group optionally substituted with at least one substituent selected from the group consisting of a hydroxy group, a carboxy group, an acetyl group, an amino group in which one or two hydrogen atoms are optionally substituted with a methyl group or methyl groups, a sulfo group, and a C₁₋₄ alkoxy group.

2. The imprint material according to claim 1, wherein the component (B) and the component (D) comprise one or two compounds of formulae (2a) and (4a), respectively: 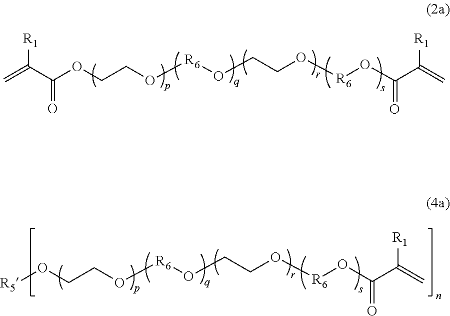
wherein each R₁ is independently a hydrogen atom or a methyl group; R₅′ is a trivalent, tetravalent, pentavalent, or hexavalent organic group having a carbon atom number of 3 to 10 or a trivalent, tetravalent, pentavalent, or hexavalent hydrocarbon group having a carbon atom number of 3 to 10, which has an ether bond in a main chain; R₆ is a trimethylene group or a propylene group; and p, q, r, and s are each independently an integer of 0, or 1 or more, and satisfy the relational expression 1≤(p+q+r+s)≤30.

3. The imprint material according to claim 1, wherein a content of the component (A) is 1% by mass or more and 40% by mass or less, based on a total mass of the components (A), (B), (C), and (D).

4. The imprint material according to claim 1, wherein a content of the component (C) is 1% by mass or more and 40% by mass or less, based on a total mass of the components (A), (B), (C), and (D).

5. The imprint material according to claim 1, further comprising, as a component (F), one or two compounds of formula (5): 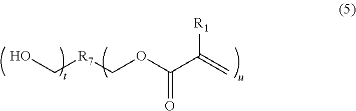
(wherein each R₁ is independently a hydrogen atom or a methyl group; R₇ is a tetravalent, pentavalent, or hexavalent organic group having a carbon atom number of 1 to 9 or a tetravalent, pentavalent, or hexavalent hydrocarbon group having a carbon atom number of 1 to 9, which has an ether bond in a main chain; t is 0 or 1; and u is an integer from 3 to 6).

6. The imprint material according to claim 1, further comprising a silicone compound as a component (G).

7. The imprint material according to claim 1, further comprising a surfactant as a component (H).

8. The imprint material according to claim 1, further comprising a solvent as a component (I).

9. A method for producing a film having a pattern transferred thereon, comprising the steps of:
applying the imprint material according to claim 1 to a base material to form a film; and
bringing a mold on which a pattern is formed into contact with the film by using a photoimprinting apparatus, pressure-bonding the film to the mold, photocuring the film, and then releasing the film from the mold to thereby transfer the pattern onto the film.
